(19) United States
(12) Patent Application Publication
(10) Pub. No.: US 2023/0296699 A1
(43) Pub. Date: Sep. 21, 2023

(54) HALL SENSOR AND MANUFACTURING METHOD OF HALL SENSOR

(71) Applicant: ROHM Co., LTD., Kyoto (JP)

(72) Inventor: Hirotoshi Kubo, Kyoto (JP)

(21) Appl. No.: 18/051,923

(22) Filed: Nov. 2, 2022

(30) Foreign Application Priority Data
Nov. 30, 2021 (JP) 2021-193732

(51) Int. Cl. G01R 33/07; H10N 52/00; H10N 52/01

(52) U.S. Cl. CPC G01R 33/07; H10N 52/101; H10N 52/01

(57) ABSTRACT

Disclosed herein is a Hall sensor including a Hall element having a first principal surface, and a first magnetic body arranged on a side of the first principal surface, in which the first magnetic body has a first surface facing the first principal surface, and an area of a projection surface of the first magnetic body when viewed in plan from an opposite side of the Hall element is larger than an area of the first surface.

### CROSS REFERENCE TO RELATED APPLICATIONS

This application claims priority benefit of Japanese Patent Application No. JP 2021-193732 filed in the Japan Patent Office on Nov. 30, 2021. Each of the above-referenced applications is hereby incorporated herein by reference in its entirety.

### BACKGROUND

The present disclosure relates to a Hall sensor and a manufacturing method of a Hall sensor.

Japanese Patent Laid-Open No. 2016-58421 discloses a Hall sensor for detecting a magnetic field. The Hall sensor includes a substrate, a magnetic sensing layer arranged on the substrate, and a magnetic film arranged on the magnetic sensing layer.

### SUMMARY

Hall sensors are mounted in various electronic devices such as videos and personal computers, and it has been desired to further improve the detection sensitivity of a magnetic field.

The present disclosure has been made in order to solve the above-described problem, and it is desirable to provide a Hall sensor in which the detection sensitivity of a magnetic field is improved and a manufacturing method of a Hall sensor.

A Hall sensor of the present disclosure includes a Hall element and a first magnetic body. The Hall element has a first principal surface. The first magnetic body is arranged on a side of the first principal surface . The first magnetic body has a first surface facing the first principal surface. An area of a projection surface of the first magnetic body when viewed in plan from an opposite side of the Hall element is larger than an area of the first surface.

A manufacturing method of a Hall sensor of the present disclosure includes preparing a Hall element having a principal surface, forming an interlayer film having a protruding portion and a recess portion formed thereon on the principal surface, and forming a magnetic body so as to cover the protruding portion and the recess portion. The magnetic body has a magnetic surface facing the principal surface. An area of a projection surface of the magnetic body when viewed in plan from an opposite side of the Hall element is larger than an area of the magnetic surface.

A manufacturing method of a Hall sensor of the present disclosure includes preparing a Hall element having a principal surface, forming a magnetic body having a magnetic surface, and bonding the Hall element and the magnetic body with an adhesive such that the principal surface and the magnetic surface face each other. An area of a projection surface of the magnetic body when viewed in plan from an opposite side of the Hall element is larger than an area of the magnetic surface.

According to the present disclosure, it is possible to provide a Hall sensor in which the detection sensitivity of a magnetic field is improved and a manufacturing method of a Hall sensor.

### BRIEF DESCRIPTION OF THE DRAWINGS

FIG. 1 depicts a configuration example of a magnetic sensor to which a Hall sensor of a first embodiment is applied;

FIG. 2 is a cross-sectional view of the Hall sensor;

FIG. 3 is a perspective view of a first magnetic body and a Hall element;

FIG. 4 is a diagram of the first magnetic body viewed in plan from a second surface in the Z-axis direction;

FIG. 5 is a diagram for explaining a magnetism collection effect of the Hall sensor of the first embodiment;

FIG. 6 is a diagram for explaining a first magnetic body of a modification of the first embodiment;

FIG. 7 is a diagram for explaining the first magnetic body of another modification of the first embodiment;

FIG. 8 is a diagram for explaining the first magnetic body of another modification of the first embodiment;

FIG. 9 is a diagram for explaining the first magnetic body of another modification of the first embodiment;

FIG. 10 is a diagram for explaining the first magnetic body of another modification of the first embodiment;

FIG. 11 is a diagram for explaining the first magnetic body of another modification of the first embodiment;

FIG. 12 is a diagram for explaining the first magnetic body of another modification of the first embodiment;

FIG. 13 is a diagram for explaining the first magnetic body of another modification of the first embodiment;

FIGS. 14A and 14B are diagrams for explaining the first magnetic body of another modification of the first embodiment;

FIGS. 15A and 15B are diagrams for explaining the first magnetic body of another modification of the first embodiment;

FIG. 16 is a cross-sectional view of a Hall sensor of a second embodiment;

FIG. 17 is a cross-sectional view of the Hall sensor of the second embodiment;

FIG. 18 is a cross-sectional view of the Hall sensor of the second embodiment;

FIG. 19 is a cross-sectional view of the Hall sensor of the second embodiment;

FIGS. 20A to 20E are diagrams for explaining a first manufacturing method of the Hall sensor;

FIG. 21 is a diagram of a Hall element and other components in a state of FIG. 20D viewed in plan from a Z-axis direction;

FIGS. 22A to 22E are diagrams for explaining a second manufacturing method of the Hall sensor;

FIG. 23 is a flowchart of the first manufacturing method or the second manufacturing method;

FIGS. 24A to 24C are diagrams for explaining a third manufacturing method of the Hall sensor;

FIG. 25 is a flowchart of the third manufacturing method;

FIG. 26 is a diagram for explaining members used for explaining simulation results;

FIG. 27 is a perspective view of a member of an experimental example 1, an experimental example 5, and an experimental example 6;

FIG. 28 is a perspective view of a member of an experimental example 2;

FIG. 29 is a perspective view of a member of an experimental example 3;

FIG. 30 is a perspective view of a member of an experimental example 4;

FIG. 31 is a table summarizing simulation results of the experimental example 1 to the experimental example 6;

FIG. 32 is a diagram for depicting the magnetic flux density in the experimental example 1;

FIG. 33 is a diagram for depicting the magnetic flux density in the experimental example 2;

FIG. 34 is a diagram for depicting the magnetic flux density in the experimental example 3;

FIG. 35 is a diagram for depicting the magnetic flux density in the experimental example 4;

FIG. 36 is a diagram for depicting the magnetic flux density in the experimental example 5;

FIG. 37 is a diagram for depicting the magnetic flux density in the experimental example 6; and

FIG. 38 is a diagram for explaining the simulation results.

### DETAILED DESCRIPTION OF THE PREFERRED EMBODIMENTS

Hereinafter, embodiments of the present disclosure will be described in detail with reference to the drawings. It should be noted that the same reference numerals are given to the same or corresponding parts in the drawings, and the description thereof will not be repeated.

### First Embodiment

### Magnetic Sensor

At present, magnetic sensors have been used in videos, personal computers, cellular phones, digital cameras, air conditioners, washing machines, automobiles, and other products we have around us. Therefore, a Hall sensor having high magnetic field detection sensitivity has been desired. In the first embodiment, a Hall sensor having high magnetic field detection sensitivity will be described.

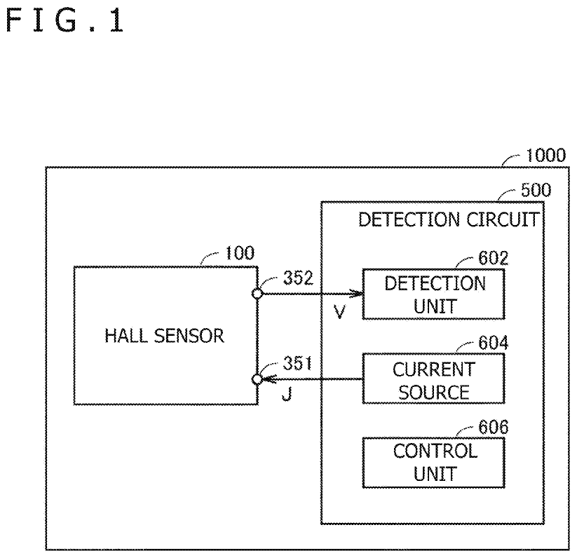

FIG. 1 depicts a configuration example of a magnetic sensor 1000 to which a Hall sensor 100 according to the first embodiment is applied. The magnetic sensor 1000 includes the Hall sensor 100 and a detection circuit 500. The Hall sensor 100 has a first electrode 351 and a second electrode 352. The detection circuit 500 has a current source 604, a detection unit 602, and a control unit 606. The control unit 606 controls the current source 604 and the detection unit 602. The current source 604 is electrically connected to the first electrode 351. The detection unit 602 is electrically connected to the second electrode 352.

Under the control of the control unit 606, the current source 604 supplies a driving current J to the Hall sensor 100 via the first electrode 351. The Hall sensor 100 outputs a Hall voltage generated in accordance with a magnetic field acting on a Hall element to be described later by the driving current J. The Hall voltage is output to the detection unit 602 via the second electrode 352. The detection unit 602 detects a magnetic field acting on the Hall sensor 100 on the basis of the Hall voltage output from the Hall sensor 100. In addition, a voltage source may be provided instead of the current source 604. The voltage source supplies a driving voltage for generating the Hall voltage in the Hall sensor 100 to the Hall sensor 100.

### Hall Sensor

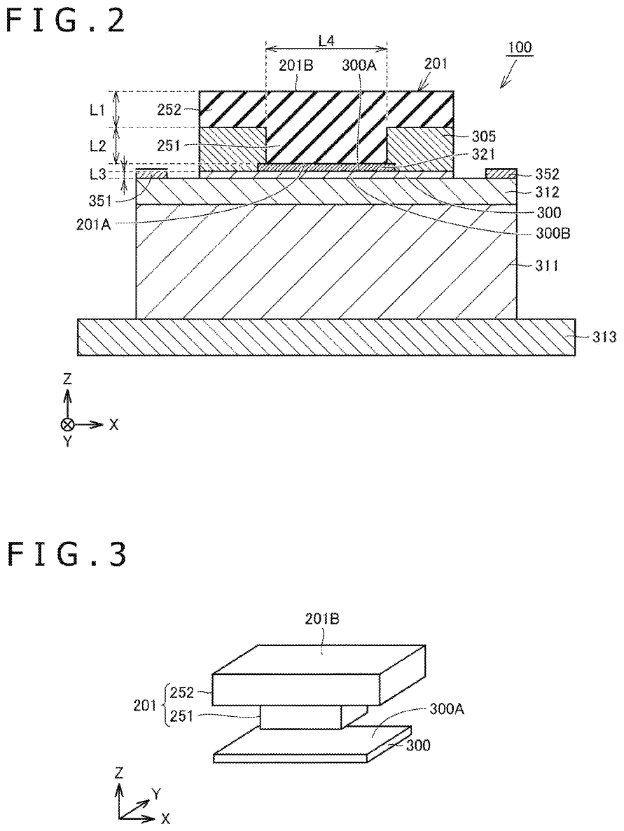

FIG. 2 is a diagram for explaining the Hall sensor 100. In the present embodiment, a thickness direction of the Hall sensor 100 is assumed as a Z-axis direction. In addition, two axes perpendicular to the Z-axis direction are assumed as an X-axis and a Y-axis. The X-axis direction is the direction of the driving current J applied to the Hall sensor 100. The Y-axis direction is the direction of the generated Hall voltage. FIG. 2 is a cross-sectional view in an XZ plane (a plane perpendicular to the Y-axis) of the Hall sensor 100.

In the example of FIG. 2, the Hall sensor 100 includes a Hall element 300, a first magnetic body 201, an interlayer film 321, an interlayer film 305, a first substrate 311, a second substrate 312, and a frame 313. In the example of FIG. 2, the frame 313, the first substrate 311, the second substrate 312, the Hall element 300, the interlayer film 321, and the first magnetic body 201 are laminated. The Z-axis direction is also the lamination direction of these members.

The frame 313 has a thin plate shape. Members (the Hall element 300, the first magnetic body 201, and other components) other than the frame 313 of the Hall sensor 100 are arranged on the frame 313. Thus, the members other than the frame 313 can stably be arranged in the magnetic sensor 1000.

The material of the frame 313 is, for example, copper. The first substrate 311 is arranged on the frame 313. The first substrate 311 includes a gallium arsenide substrate, an indium arsenide substrate, a silicon substrate, or other semiconductor substrates. The gallium arsenide substrate is also referred to as a “GaAs substrate.” In addition, the indium arsenide substrate is also referred to as an “InAs substrate.” The first electrode 351 and the second electrode 352 (see FIG. 1) are formed at both ends of the first substrate 311.

The second substrate 312 is smaller than the first substrate 311. The second substrate 312 is arranged on the first substrate 311. The second substrate 312 includes a gallium arsenide substrate, an indium arsenide substrate, a silicon substrate, or other semiconductor substrates. The same material or different materials may be used for the first substrate 311 and the second substrate 312. The second substrate 312 functions as a wiring layer.

The Hall element 300 and the interlayer film 305 are arranged on the second substrate 312. The interlayer film 305 is, for example, an oxide film. In addition, the Hall element 300 includes a gallium arsenide substrate, an indium arsenide substrate, silicon, indium antimonide (InSb), other semiconductors, or other materials.

In the embodiment, the Hall element 300 has a rectangular parallelepiped or cubic shape (see FIG. 3 to be described later). It should be noted that the Hall element 300 may have other shapes. Other shapes may be, for example, any shape such as a thin plate shape, a cylindrical shape, and a polygonal columnar shape.

In addition, the Hall element 300 has a first principal surface 300A and a second principal surface 300B. The first principal surface 300A and the second principal surface 300B are surfaces positioned opposite to each other in the Z-axis direction. More specifically, the first principal surface 300A and the second principal surface 300B may be surfaces facing each other in the Z-axis direction. Typically, the first principal surface 300A and the second principal surface 300B are planes, and the first principal surface 300A and the second principal surface 300B are parallel to each other. It should be noted that the “plane” in the embodiment may be not only a perfect plane but also a plane in which a few recess portions, protruding portions, or other portions are formed to improve the detection sensitivity of the magnetic field. In addition, the “parallel” in the embodiment may be not only perfectly parallel but also a relation in which two extension surfaces are brought into contact with each other to improve the detection sensitivity of the magnetic field.

The first principal surface 300A is a surface to which a magnetic flux (magnetic field) is input. A Hall voltage is generated on the basis of the magnetic flux (magnetic field) input to the first principal surface 300A.

The Hall element 300 is arranged on the second substrate 312 such that the second principal surface 300B faces the second substrate 312.

The first magnetic body 201 is arranged on the first principal surface 300A side of the Hall element 300. The first magnetic body 201 has a first surface 201A and a second surface 201B. The first surface 201A and the second surface 201B are surfaces positioned opposite to each other in the Z-axis direction. More specifically, the first surface 201A and the second surface 201B may be surfaces facing each other in the Z-axis direction. Typically, the first surface 201A and the second surface 201B are planes, and the first surface 201A and the second surface 201B are parallel to each other.

The first magnetic body 201, a second magnetic body, and a third magnetic body to be described later may include any one of a magnetic semiconductor, an oxide magnetic body, and a metal magnetic body. The metal magnetic body is, for example, permalloy.

In addition, the first magnetic body 201, the second magnetic body, and the third magnetic body may include GaMnAs. GaMnAs is formed by epitaxial growth on a GaAs substrate. Molecular beam epitaxy (MBE), metal organic chemical vapor deposition (MOCVD), or other methods is adopted as the manufacturing method.

In addition, the first magnetic body 201, the second magnetic body, and the third magnetic body may include InMnAs. InMnAs is formed by epitaxial growth on an InAs substrate. MBE, MOCVD, or other methods can be adopted as the manufacturing method. The same material or different materials may be used for the first magnetic body 201, the second magnetic body, and the third magnetic body.

The first magnetic body 201 is arranged on the Hall element 300 such that the first surface 201A faces the first principal surface 300A. FIG. 2 depicts an example in which the interlayer film 321 is interposed between the first surface 201A and the first principal surface 300A. However, the Hall sensor 100 need not include the interlayer film 321. In addition, in the example of FIG. 2, the cross section of the first magnetic body 201 perpendicular to the first surface 201A (that is, the cross section in the XZ plane) is T-shaped.

In addition, for the sake of convenience, the first magnetic body 201 will separately be described as a first magnetic part 251 and a second magnetic part 252 in some cases. The first magnetic part 251 is a member having the first surface 201A of the first magnetic body 201. The second magnetic part 252 is a member having the second surface 201B of the first magnetic body 201. It should be noted that the first magnetic body 201 may have a structure in which the first magnetic part 251 and the second magnetic part 252 are integrated. In addition, the first magnetic body 201 may have a structure in which the first magnetic part 251 and the second magnetic part 252 are separate.

The inventors have confirmed that it is preferable that a thickness L1 (a length in the Z-axis direction) of the first magnetic part 251 is typically a value of 5 μm or more and 20 μm or less. In the embodiment, L1 is 15 μm. In addition, the inventors have confirmed that it is preferable that a thickness L2 (a length in the Z-axis direction) of the second magnetic part 252 is typically a value of 0.1 μm or more and 20 μm or less. In the embodiment, L2 is 15 μm. A thickness L3 (a length in the Z-axis direction) of the Hall element 300 is typically a value of 0.4 μm or more and 1.5 μm or less. In addition, a length L4 of the first magnetic part 251 in the X-axis direction is, for example, 50 μm.

FIG. 3 is a perspective view of the first magnetic body 201 and the Hall element 300. In the example of FIG. 3, each of the first magnetic part 251, the second magnetic part 252, and the Hall element 300 has a rectangular parallelepiped shape.

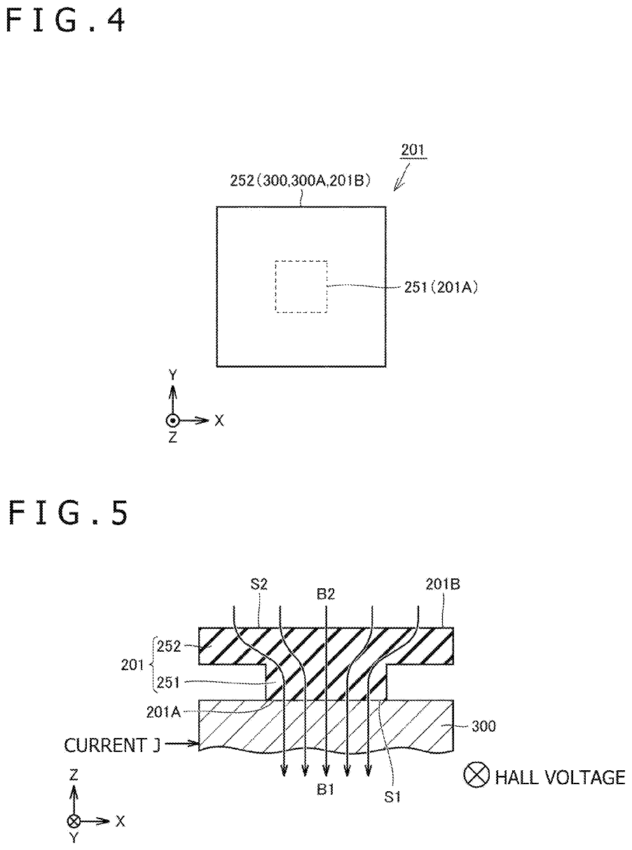

FIG. 4 is a diagram of the first magnetic body 201 viewed in plan from the second surface 201B in the Z-axis direction. In the example of FIG. 4, the first surface 201A of the first magnetic part 251 is depicted by a broken line, and the second surface 201B of the second magnetic part 252 is depicted by a solid line. In the example of FIG. 4, both the first surface 201A and the second surface 201B are rectangular. It should be noted that at least one of the first surface 201A and the second surface 201B may have other shapes. Other shapes may be, for example, a circular shape, a triangular shape, a rectangular shape, or a P-gonal (P is an integer equal to or larger than 5) shape. In addition, as depicted in FIG. 4, the area S2 of the second surface 201B is larger than the area S1 of the first surface 201A.

That is, the following equation (1) is established.

S2>S1 (1)

In addition, the shapes and areas of the second surface 201B and the first principal surface 300A are the same in the embodiment. Thus, the area of the first principal surface 300A is also the area S2.

### Magnetism Collection Effect

FIG. 5 is a diagram for explaining a magnetism collection effect of the Hall sensor 100 of the embodiment. The magnetic flux input to the first magnetic body 201 is referred to as a “magnetic flux ϕ,” the magnetic flux density of the first surface 201A is referred to as “B1,” and the magnetic flux density of the second surface 201B is referred to as “B2.” In addition, as described in FIG. 5, the area of the first surface 201A is “S1,” and the area of the second surface 201B is “S2.” In addition, in the embodiment, the area S2 is 190×190 μm², and the area S1 is 50×50 μm².

When the magnetic flux density B1, the magnetic flux density B2, the area S1, and the area S2 are used, the following equation (2) is established.

ϕ=B1·S1=B2·S2 (2)

Thus, the following equations (3) and (4) are established.

B1=ϕ/S1 (3)

B2=ϕ/S2 (4)

In addition, the following equation (5) is established from the equations (1), (3), and (4).

B1>B2 (5)

In FIG. 5, the magnetic flux is depicted by arrows. As depicted in FIG. 5, the magnetic flux input from the second surface 201B passes through the second magnetic part 252. Then, the magnetic flux is input to the first magnetic part 251 having the first surface 201A, so that the magnetic flux density is increased. Thus, as indicated in the equation (5), the magnetic flux density B1 becomes larger than the magnetic flux density B2.

In addition, the Hall voltage V generated in the Hall element 300 and the magnetic flux density B of the magnetic field applied to the Hall element 300 satisfy the following equation (6).

V=α·B (6)

Here, α is a proportional constant larger than 1. As indicated in the equation (6), as the magnetic flux density B becomes larger, the Hall voltage V (or the absolute value of the Hall voltage V) becomes larger. In addition, the magnetic flux density B of the magnetic field applied to the Hall element 300 can be regarded as the same as the magnetic flux density B1.

For example, in a Hall sensor (hereinafter, referred to as a “Hall sensor of a comparative example”) in which the first area S1 and the second area S2 are the same, since B1=B2 is satisfied, the Hall voltage V cannot be increased, and the detection sensitivity of the magnetic field of the Hall sensor cannot be improved.

On the contrary, in the Hall sensor 100 of the embodiment, the magnetic flux density B1 can be made larger than the magnetic flux density B2 as indicated in the equation (5). Accordingly, the Hall sensor 100 of the embodiment can increase the Hall voltage as compared with the Hall sensor of the comparative example. As a result, the Hall sensor 100 can improve the detection sensitivity of the magnetic field as compared with the Hall sensor of the comparative example.

In addition, as the area of the second surface 201B becomes larger, more magnetic flux can be input to the first magnetic body 201, and as a result, the magnetic flux density B1 can be increased. However, in a case where the area of the second surface 201B is excessively large, the size of the Hall sensor 100 in the XY plane is enormously increased.

In addition, as the second area S2 of the second surface 201B becomes larger, more magnetic flux can be input to the first magnetic body 201. However, if the second area S2 of the second surface 201B is excessively large, the size of the Hall sensor 100 is increased. Accordingly, the second area S2 of the second surface 201B is the same as the area of the first principal surface 300A in the embodiment. With such a configuration, the magnetic flux density B1 of the first surface 201A can be increased while suppressing the size of the Hall sensor 100.

It should be noted that, as a modification, the second area S2 of the second surface 201B may be less than the area of the first principal surface 300A. According to such a configuration, the size of the Hall sensor 100 can be suppressed.

In addition, a value (ratio P) obtained by dividing the area S2 by the area S1 is 14.44 in the embodiment. The inventors have confirmed that the preferred range of the ratio P is 1.1 or more and 16 or less.

### Other Shapes of First Magnetic Body

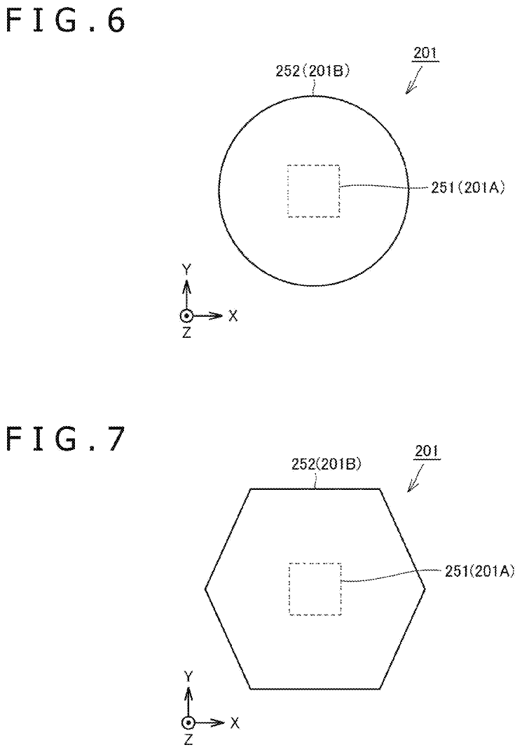

Next, other shapes of the first magnetic body 201 will be described. In addition, if the area S2 of the second surface 201B is larger than the area S1 of the first surface 201A, the first magnetic body 201 may have other shapes. FIG. 6 to FIG. 11 are diagrams of the first magnetic bodies 201 of modifications having other shapes viewed in plan from the second surface 201B in the Z-axis direction. It should be noted that, in each of FIG. 6 to FIG. 11, the first surface 201A of the first magnetic part 251 is depicted by a broken line, and the second surface 201B of the second magnetic part 252 is depicted by a solid line.

In the example of FIG. 6, the second surface 201B has a circular shape. That is, the second magnetic part 252 has a cylindrical shape. In addition, the first surface 201A has a rectangular shape. That is, the first magnetic part 251 has a rectangular parallelepiped shape.

In the example of FIG. 7, the second surface 201B has a polygonal shape (a hexagonal shape in FIG. 7). That is, the second magnetic part 252 has a polygonal columnar shape (a hexagonal columnar shape in FIG. 7). In addition, the first surface 201A has a rectangular shape. That is, the first magnetic part 251 has a rectangular parallelepiped shape.

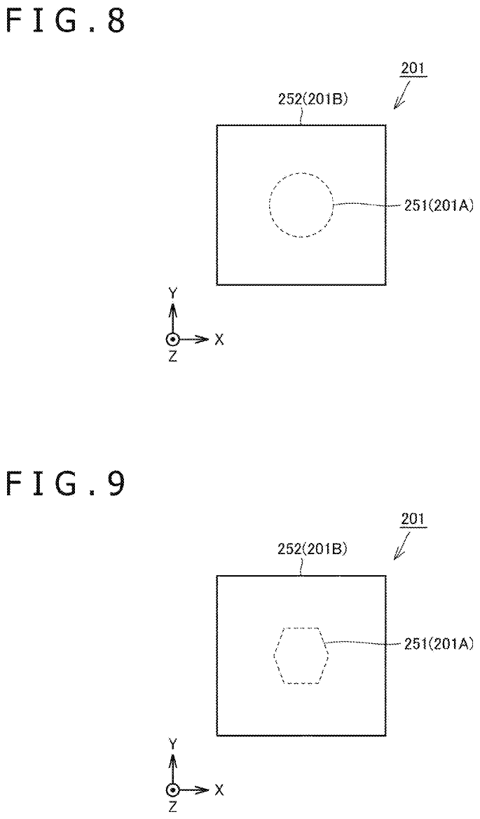

In the example of FIG. 8, the second surface 201B has a rectangular shape. That is, the second magnetic part 252 has a rectangular parallelepiped shape. In addition, the first surface 201A has a circular shape. That is, the first magnetic part 251 has a cylindrical shape.

In the example of FIG. 9, the second surface 201B has a rectangular shape. That is, the second magnetic part 252 has a rectangular parallelepiped shape. In addition, the first surface 201A has a hexagonal shape. That is, the first magnetic part 251 has a hexagonal columnar shape.

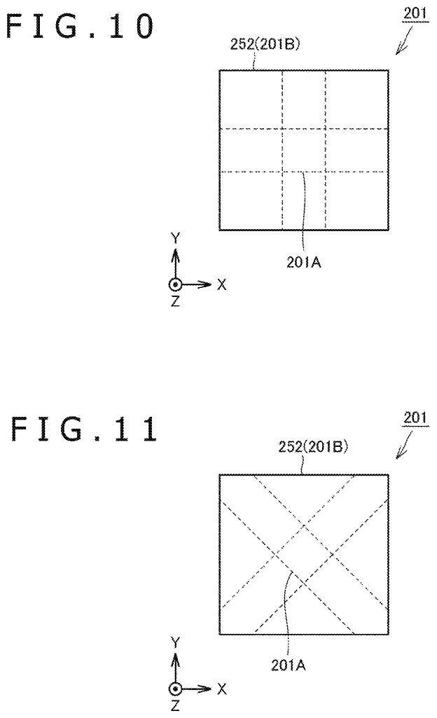

In the example of FIG. 10, the second surface 201B has a rectangular shape. That is, the second magnetic part 252 has a rectangular parallelepiped shape. In addition, the first surface 201A has a cross shape. In the example of FIG. 10, in a case where the first magnetic body 201 is viewed in plan from the second surface 201B in the Z-axis direction, the four sides of tip ends of the cross shape of the first surface 201A are brought into contact with the four sides of the rectangular second surface 201B. In the example of FIG. 10, the first magnetic part 251 has a columnar shape having a cross shape in the middle and a rectangular bottom surface (first surface 201A).

In the example of FIG. 11, the second surface 201B has a rectangular shape. That is, the second magnetic part 252 has a rectangular parallelepiped shape. In addition, the first surface 201A has a cross shape. In the example of FIG. 11, in a case where the first magnetic body 201 is viewed in plan from the second surface 201B in the Z-axis direction, tip ends of the cross shape of the first surface 201A are brought into contact with the four vertexes of the rectangular second surface 201B. In the example of FIG. 11, the first magnetic part 251 has a columnar shape having a cross shape in the middle and a rectangular bottom surface (first surface 201A).

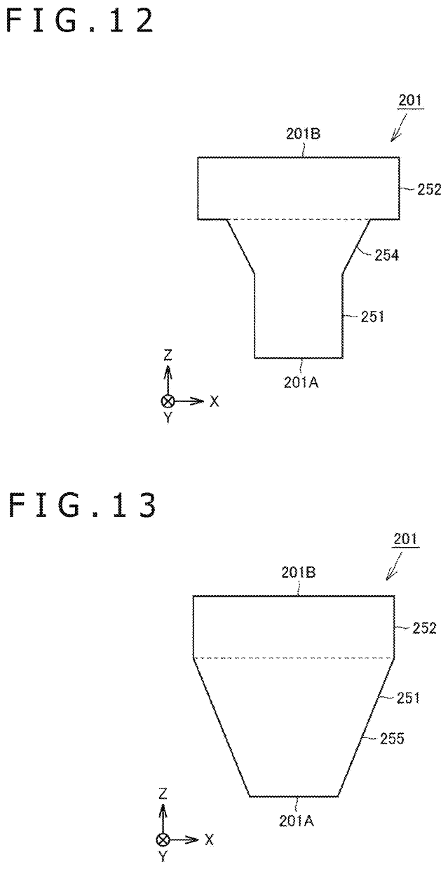

FIG. 12 to FIGS. 15A and 15B are diagrams of the first magnetic bodies 201 of modifications having other shapes viewed in plan in the Y-axis direction. In each of the examples of FIG. 12 and FIG. 13, a broken line is provided for the sake of convenience to distinguish the first magnetic part 251 from the second magnetic part 252.

In the example of FIG. 12, a tapered portion 254 is formed at a joint portion between the second magnetic part 252 and the first magnetic part 251. In the example of FIG. 13, a tapered portion 255 is formed from the second magnetic part 252 to the first surface 201A. In other words, the outer peripheral surface of the first magnetic part 251 is a tapered surface.

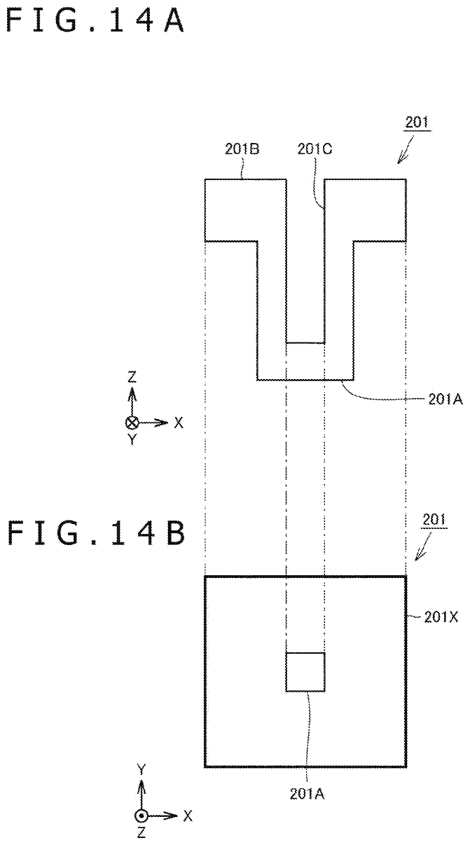

In the example of FIGS. 14A and 14B, FIG. 14A and FIG. 14B are depicted. FIG. 14A is a diagram of the first magnetic body 201 of the modification viewed in plan in the Y-axis direction. FIG. 14B is a diagram of the first magnetic body 201 of the modification viewed in plan from the second surface 201B in the Z-axis direction.

The first magnetic body 201 of FIGS. 14A and 14B has a hole 201C formed in the center portion of the T-shaped first magnetic body 201 depicted in FIG. 2 and other figures. The cross section of the hole 201C has a rectangular shape. In addition, the first surface 201A has a rectangular shape.

In FIG. 14B, a projection surface 201X is depicted. Here, the projection surface 201X is a surface when viewing the first magnetic body 201 in plan from the opposite side of the Hall element 300 (from the second surface 201B). In other words, the projection surface 201X is a surface projected onto a plane perpendicular to the Z-axis direction in a case where the first magnetic body 201 is projected onto the plane. In the example of FIG. 14B, the projection surface 201X is a surface surrounded by a thick line. The projection surface 201X corresponds to the second surface 201B. In addition, in the example of FIG. 14B, the first surface 201A is depicted by a broken line.

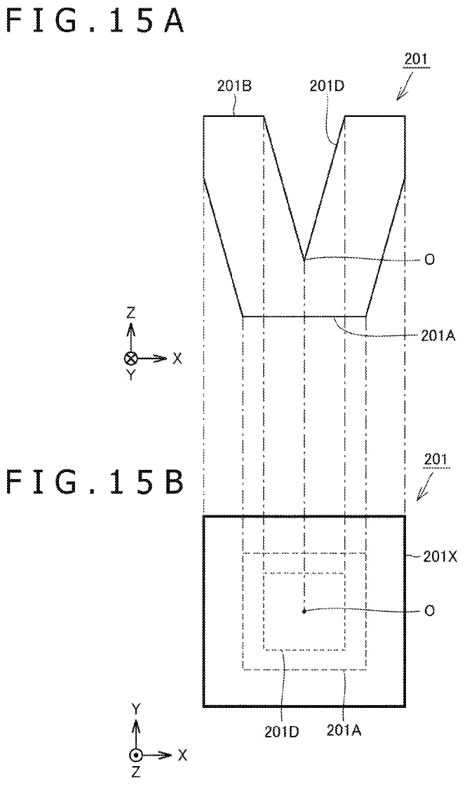

In the example of FIGS. 15A and 15B, FIG. 15A and FIG. 15B are depicted. FIG. 15A is a diagram of the first magnetic body 201 of the modification viewed in plan in the Y-axis direction. FIG. 15B is a diagram of the first magnetic body 201 of the modification viewed in plan from the second surface 201B in the Z-axis direction.

The first magnetic body 201 of FIGS. 15A and 15B has a hole 201D formed in the center portion of the first magnetic body 201 depicted in FIG. 13. The cross section of the hole 201D has a triangular shape. In addition, the first surface 201A has a rectangular shape. In FIG. 15B, the projection surface 201X is depicted. In addition, in the example of FIG. 15B, the first surface 201A is depicted by a broken line.

As depicted in FIG. 14B or FIG. 15B, the area of the projection surface 201X is larger than that of the first surface 201A. With such a configuration, the magnetic flux density B1 can be made larger than the magnetic flux density BX of the projection surface 201X. Therefore, even in the Hall sensor including the first magnetic body 201 depicted in each of FIGS. 14A and 14B and FIGS. 15A and 15B, the detection sensitivity of the magnetic field can be improved.

In addition, in the embodiment, the cross section (that is, the cross section in the XZ plane) of the first magnetic body 201 depicted in FIG. 6 to FIG. 15B perpendicular to the first surface 201A is T-shaped or substantially T-shaped. It should be noted that any of the cross sections of the first magnetic body 201 depicted in FIG. 6 to FIG. 15B may belong to other shapes. For example, the cross section of the first magnetic body 201 of FIGS. 15A and 15B may belong to a V-shape. In addition, in FIGS. 6, 7, 10, and 11, the first surface 201A may have other shapes. Other shapes may be, for example, a circular shape, a triangular shape, a rectangular shape, or a P-gonal (P is an integer equal to or larger than 5) shape.

### Second Embodiment

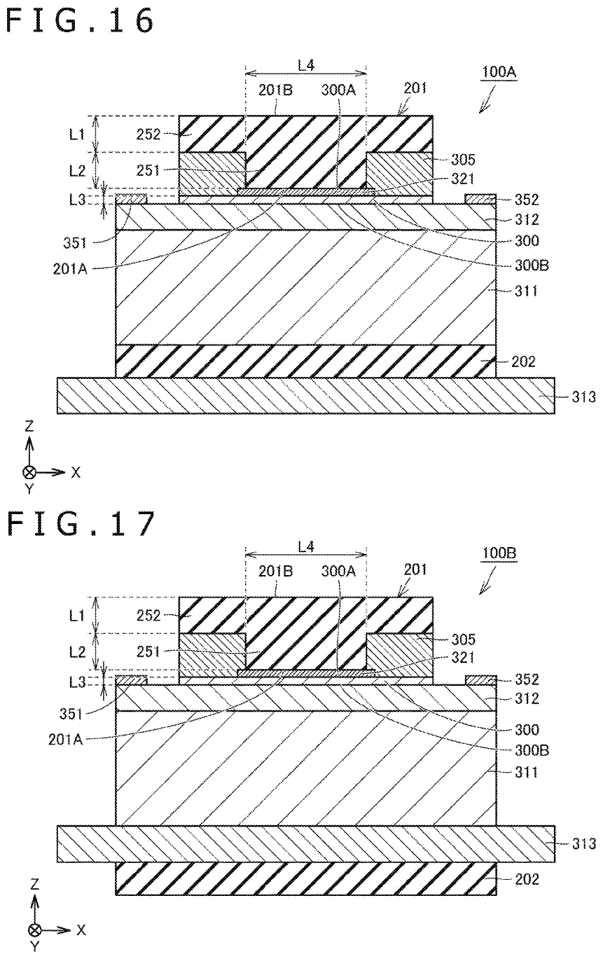

A Hall sensor of a second embodiment has a second magnetic body 202 in addition to the first magnetic body 201. FIG. 16 to FIG. 19 are diagrams for explaining each example of the second embodiment. In the examples of FIG. 16 to FIG. 19, the second magnetic body 202 is arranged on the second principal surface 300B side of the Hall element 300.

FIG. 16 is a cross-sectional view of a Hall sensor 100A of a first example. In the Hall sensor 100A, the second magnetic body 202 is arranged between the first substrate 311 and the frame 313. In the example of FIG. 16, the first substrate 311 is arranged between the second magnetic body 202 and the second substrate 312.

The second magnetic body 202 may be formed as a back metal of the Hall element 300. In addition, the second magnetic body 202 may be formed by being pasted to the second principal surface 300B of the Hall element 300 with an adhesive or other materials.

With the configuration of the Hall sensor 100A, the first magnetic body 201 and the second magnetic body 202 can form a strong magnetic flux loop as compared with the Hall sensor 100 of the first embodiment. Therefore, the Hall sensor 100A of the first example can further increase the magnetic flux density B1 as compared with the Hall sensor 100.

FIG. 17 is a cross-sectional view of a Hall sensor 100B of a second example. In the Hall sensor 100B, the frame 313 is arranged between the Hall element 300 and the second magnetic body 202. In other words, the second magnetic body 202 is arranged on the opposite side of the first magnetic body 201 and the Hall element 300 in the frame 313. The second magnetic body 202 is formed by being pasted to the frame 313 with an adhesive or other materials.

Even in the configuration of the Hall sensor 100B, the first magnetic body 201 and the second magnetic body 202 can form a strong magnetic flux loop as compared with the Hall sensor 100 of the first embodiment. Therefore, the Hall sensor 100B of the second example can further increase the magnetic flux density B1 as compared with the Hall sensor 100.

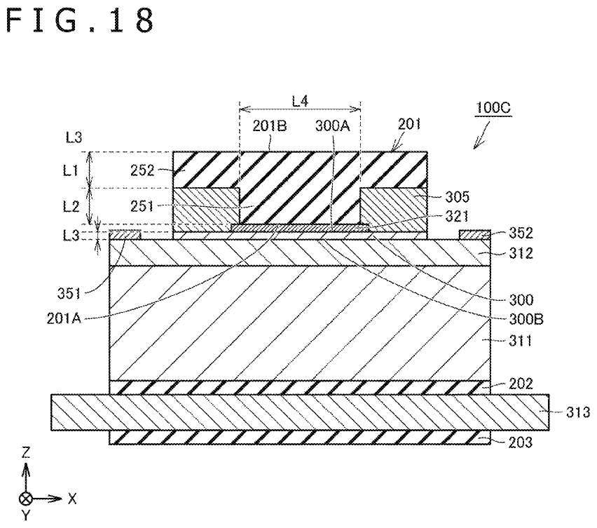

FIG. 18 is a cross-sectional view of a Hall sensor 100C of a third example. The second magnetic body 202 of the Hall sensor 100C is formed by plating. The second magnetic body 202 is arranged between the first substrate 311 and the frame 313.

Here, in order to form a magnetic flux loop, it is preferable that a thickness of the second magnetic body 202 is secured to some extent. However, since the second magnetic body 202 is formed by plating, the thickness of the second magnetic body 202 tends to be reduced.

Therefore, the Hall sensor 100C also includes a third magnetic body 203. Since the thickness of the third magnetic body 203 is also added in addition to the thickness of the second magnetic body 202 in the Hall sensor 100C, the first magnetic body 201, the second magnetic body 202, and the third magnetic body 203 can form a magnetic flux loop. In addition, the third magnetic body 203 is also formed by plating. In addition, the third magnetic body 203 is arranged on the opposite side of the first magnetic body 201, the second magnetic body 202, and the Hall element 300 in the frame 313.

According to the Hall sensor 100C, since the second magnetic body 202 is formed by plating, the thickness of the second magnetic body 202 for forming a magnetic flux loop cannot be secured in some cases. Therefore, the Hall sensor 100C has the third magnetic body 203. Thus, even in a case where the second magnetic body 202 and the third magnetic body 203 are formed by plating, a certain thickness of a magnetic body different from the first magnetic body 201 can be secured, so that a magnetic flux loop can be formed.

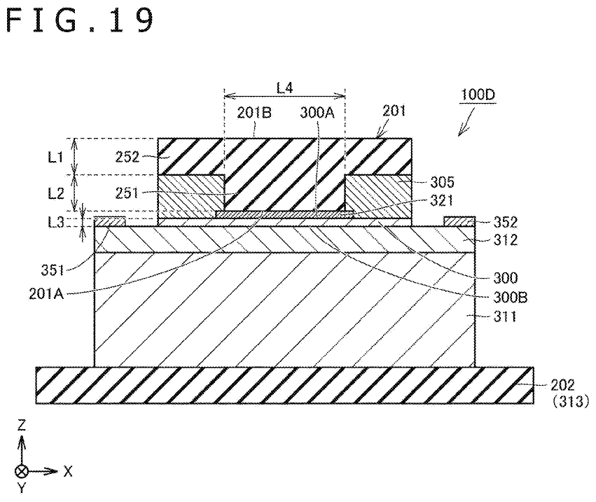

FIG. 19 is a cross-sectional view of a Hall sensor 100D of a fourth example. In the Hall sensor 100D, the frame 313 is the second magnetic body 202. That is, the frame 313 and the second magnetic body 202 are shared with each other. The Hall sensor 100D can form a magnetic flux loop. Further, since the frame 313 and the second magnetic body 202 are shared with each other in the Hall sensor 100D, the number of components can be suppressed as compared with the Hall sensor in which the frame and the second magnetic body are separate.

### Manufacturing Method of Hall Sensor

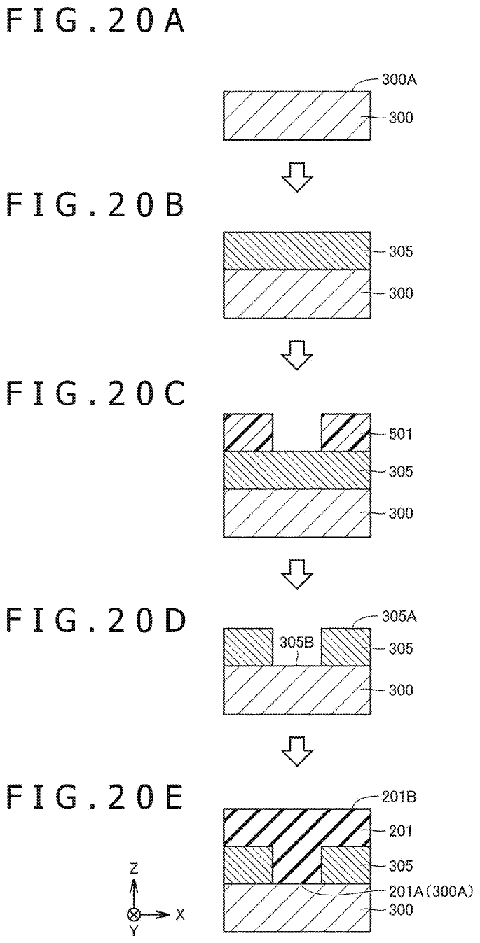

Next, a manufacturing method of the Hall sensor will be described. FIGS. 20A to 20E are diagrams for explaining a first manufacturing method of the Hall sensor. It should be noted that, in FIGS. 20A to 20E and FIG. 21 to FIG. 25 to be described later, the first magnetic body 201 and the Hall element 300 of the Hall sensor are depicted. In addition, in the description of FIG. 20A to FIG. 22E and FIGS. 24A to 24C, the dimensions of the first magnetic body 201 and the Hall element 300 are different as compared with FIG. 2 and other figures.

As depicted in FIG. 20A, the Hall element 300 having the first principal surface 300A (principal surface) is prepared. Next, as depicted in FIG. 20B, the interlayer film 305 is formed on the first principal surface 300A. The interlayer film 305 is formed by, for example, a chemical vapor deposition (CVD) method.

Next, as depicted in FIG. 20C, resists 501 are formed on the interlayer film 305. The resist 501 is, for example, a mixture composed mainly of a resin (polymer), a photosensitive material, an additive, and a solvent. The resist 501 is, for example, a mixture composed mainly of at least one of a resin (polymer), a photosensitive material, an additive, and a solvent. The resists 501 are formed on both ends of the interlayer film 305. In addition, a pattern is formed by the resists 501. This pattern is a pattern for forming the first magnetic body 201 (see FIG. 3).

Next, as depicted in FIG. 20D, the interlayer film 305 is etched in the state depicted in FIG. 20C. By this etching process, a protruding portion 305A and a recess portion 305B are formed in the interlayer film 305. By this etching process, the interlayer film 305 having the protruding portion 305A and the recess portion 305B is formed on the first principal surface 300A. Accordingly, the protruding portion 305A and the recess portion 305B are formed on the first principal surface 300A.

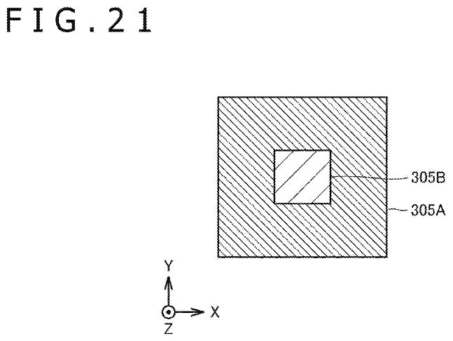

FIG. 21 is a diagram of the Hall element 300 and other components in the state of FIG. 20D viewed in plan from the Z-axis direction. In the example of FIG. 21, the interlayer film 305 (protruding portion 305A) is formed on the periphery of the rectangular first principal surface 300A. In addition, the region of the first principal surface 300A other than the protruding portion 305A is the recess portion 305B. In other words, the recess portion 305B is formed in the center portion of the interlayer film 305, and the remaining portion is the protruding portion 305A.

Next, as depicted in FIG. 20E, the first magnetic body 201 (magnetic body) is formed by a predetermined method so as to cover the protruding portion 305A and the recess portion 305B. The predetermined method is any of, for example, sputtering, deposition, plating, and other methods. In addition, the first magnetic body 201 has the first surface 201A (magnetic surface) facing the first principal surface 300A. Then, the area of the second surface 201B is larger than that of the first surface 201A.

It should be noted that, although not particularly illustrated, the second magnetic body 202 and the third magnetic body 203 described above may be laminated at a predetermined timing.

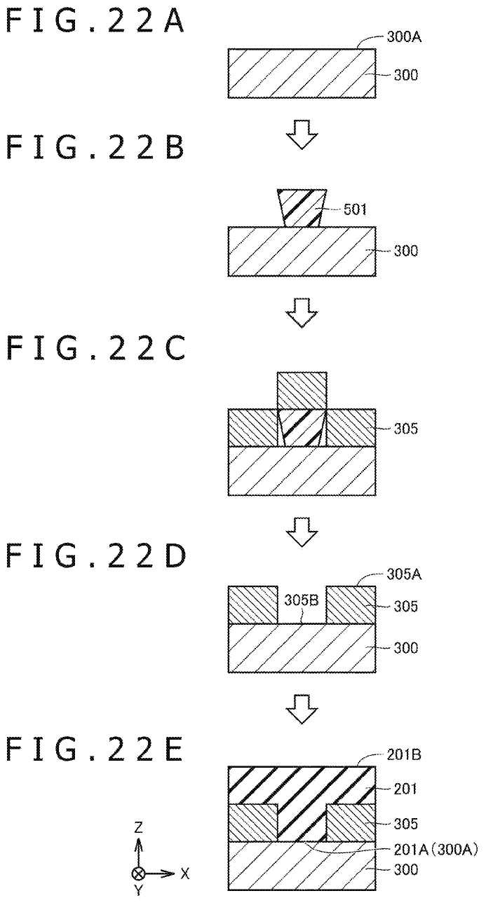

FIGS. 22A to 22E are diagrams for explaining a second manufacturing method of the Hall sensor. The second manufacturing method is a method obtained by replacing FIG. 20B and FIG. 20C with FIG. 22B and FIG. 22C, respectively.

As depicted in FIG. 22B, the resist 501 is formed in the center portion of the first principal surface 300A. Then, as depicted in FIG. 22C, the interlayer film 305 is formed on the resist 501 and regions of the first principal surface 300A other than the resist 501 by a predetermined method. The predetermined method is, for example, a CVD method or sputtering.

Next, as depicted in FIG. 22D, lift-off is performed to remove the resist 501 and the interlayer film 305 covering the resist 501. The state of FIG. 22D is similar to those of FIG. 20D and FIG. 21.

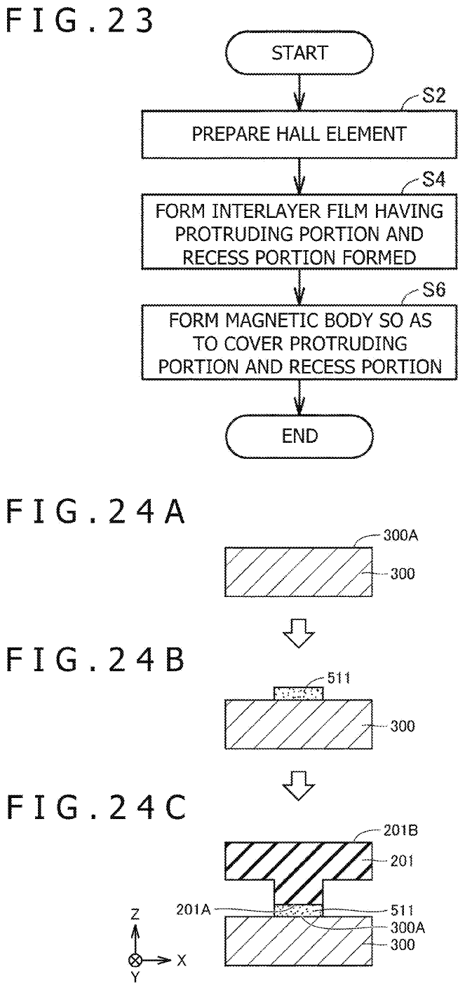

FIG. 23 is a flowchart of the first manufacturing method or the second manufacturing method. In Step S2, the Hall element 300 is prepared (FIG. 20A or FIG. 22A). Next, in Step S4, the interlayer film 305 having the protruding portion 305A and the recess portion 305B formed thereon is formed on the first principal surface 300A (see FIG. 20D or FIG. 22D). The processing of Step S4 is executed by executing the processing described in FIG. 20B and FIG. 20C or the processing described in FIG. 22B and FIG. 22C.

Next, in Step S6, the first magnetic body 201 is formed so as to cover the protruding portion 305A and the recess portion 305B (FIG. 20E or FIG. 22E).

The Hall sensor 100 can relatively simply be manufactured by the manufacturing method described in FIG. 20A to FIG. 23. In particular, as described in FIG. 2 and other figures, the shape of the first magnetic body 201 preferably has the first surface 201A and the second surface 201B facing the first surface 201A. The Hall sensor having the first magnetic body 201 can be manufactured by the relatively simple manufacturing method described in FIG. 20A to FIG. 23.

In addition, the cross section of the first magnetic body 201 perpendicular to the first surface 201A is preferably T-shaped. The Hall sensor having the first magnetic body 201 can be manufactured by the relatively simple manufacturing method described in FIG. 20A to FIG. 23.

FIGS. 24A to 24C are diagrams for explaining a third manufacturing method of the Hall sensor. As depicted in FIG. 24A, the Hall element 300 having the first principal surface 300A (principal surface) is prepared. In addition, the first magnetic body 201 is manufactured by a predetermined method in another step. The predetermined method is a punching process or an etching process (or shaping and sintering).

As depicted in FIG. 24B, an adhesive 511 is applied to the center portion of the first principal surface 300A. Then, as depicted in FIG. 24C, the Hall element 300 and the first magnetic body 201 are bonded with the adhesive 511 such that the first principal surface 300A of the Hall element 300 and the first surface 201A (magnetic surface) of the first magnetic body 201 face each other. In addition, in the example of FIGS. 24A to 24C, the adhesive 511 is applied to the Hall element 300, but may be applied to the first surface 201A of the first magnetic body 201.

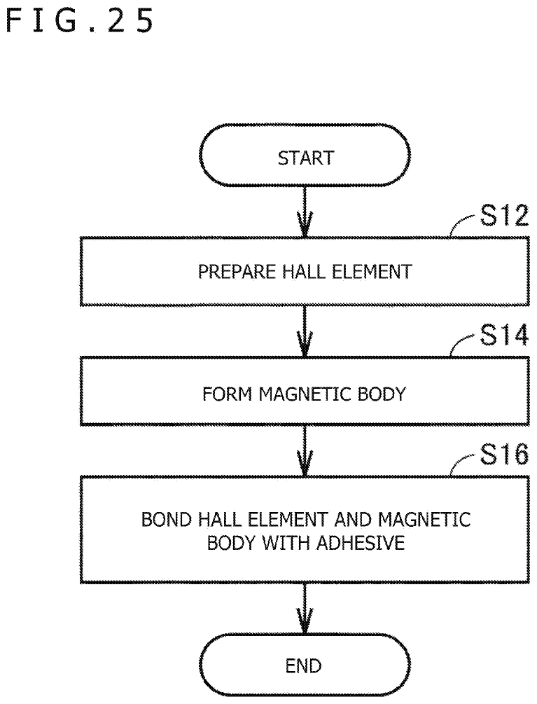

FIG. 25 is a flowchart of the third manufacturing method. In Step S12, the Hall element 300 is prepared (FIG. 24A). Next, in Step S14, the first magnetic body 201 is formed. It should be noted that the first magnetic body 201 may be formed in advance. Then, the Hall element 300 and the first magnetic body 201 are bonded with the adhesive 511.

The Hall sensor can be manufactured even by the third manufacturing method described in FIGS. 24A to 24C or FIG. 25. In addition, the Hall sensor having the first magnetic body 201 described in FIG. 6 to FIG. 15B may be manufactured by the manufacturing methods described in FIG. 20A to FIG. 25. In addition, the Hall sensor 100A to the Hall sensor 100D (see FIG. 16 to FIG. 19) may be manufactured by the manufacturing methods described in FIG. 20A to FIG. 25.

### Simulation Result

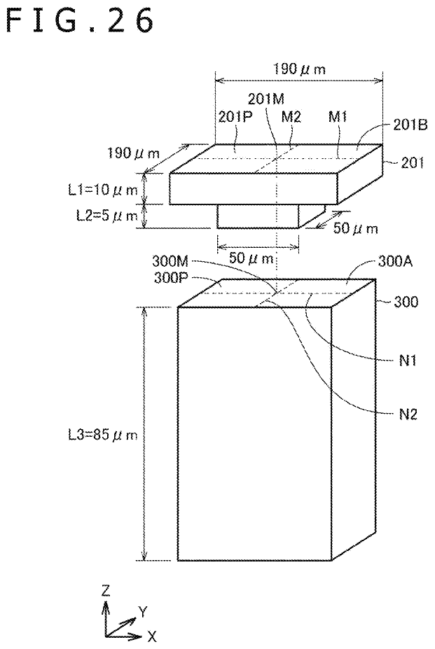

Next, simulation results indicating that the detection sensitivity of the magnetic field of the Hall sensor of the embodiment has been improved will be described. FIG. 26 to FIG. 38 are diagrams for explaining the simulation results.

FIG. 26 is a diagram for explaining the configurations of FIG. 27 to FIG. 30. FIG. 26 depicts a straight line M1 and a straight line M2 for quadrisecting the second surface 201B of the first magnetic body 201 in the XY plane. The straight line M1 is a straight line along the X-axis direction, and the straight line M2 is a straight line along the Y-axis direction.

In addition, FIG. 26 depicts a straight line N1 and a straight line N2 for quadrisecting the first principal surface 300A of the Hall element 300 in the XY plane. The straight line N1 is a straight line along the X-axis direction, and the straight line N2 is a straight line along the Y-axis direction.

The simulation results will be described by using a magnetic body member 201P and a Hall element member 300P. The magnetic body member 201P is a member obtained by quadrisecting the first magnetic body 201. The Hall element member 300P is a member obtained by quadrisecting the Hall element 300. In addition, the intersection point of the straight line M1 and the straight line M2 is a top portion 201M of the magnetic body member 201P. In addition, the intersection point of the straight line N1 and the straight line N2 is a top portion 300M of the Hall element member 300P.

In addition, for the first magnetic body 201 and the Hall element in FIG. 26 that are not quadrisected, L1=10 μm, L2=5 μm, and L3=85 μm, and the areas of the second surface 201B and the first principal surface 300A are 190×190 μm², and the area of the first surface 201A is 50×50 μm².

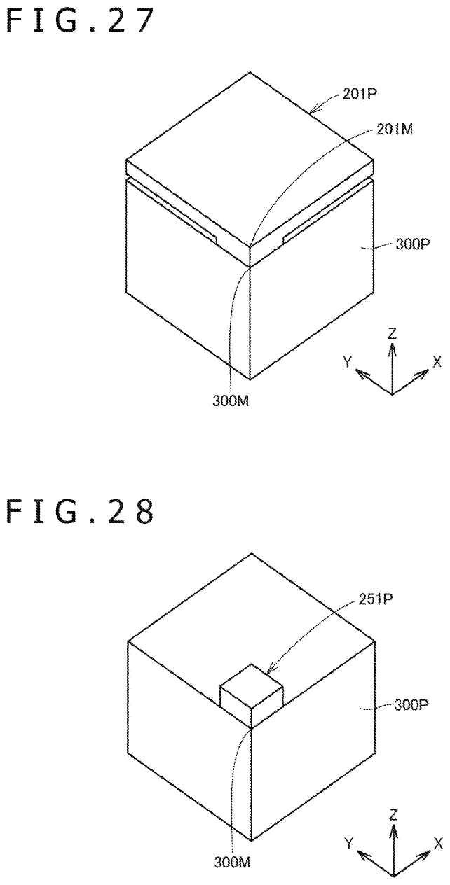

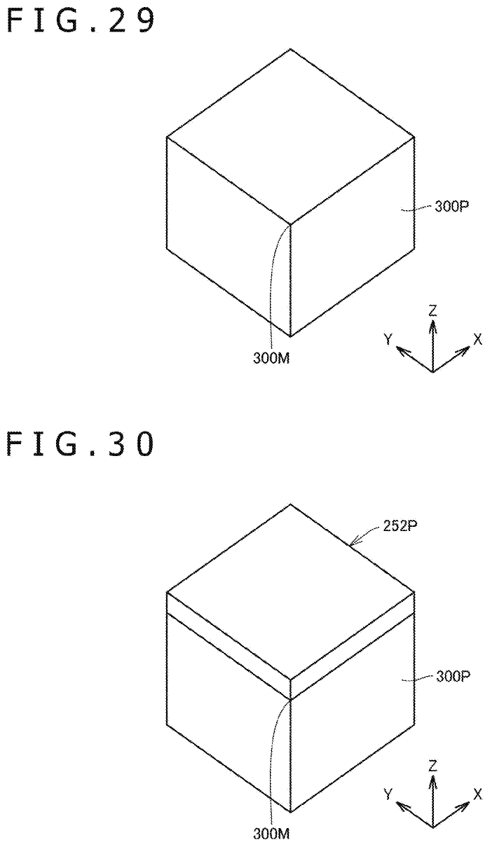

FIG. 27 is a perspective view of a member of an experimental example 1, an experimental example 5, and an experimental example 6. The member of the experimental example 1, the experimental example 5, and the experimental example 6 has the magnetic body member 201P and the Hall element member 300P. FIG. 28 is a perspective view of a member of an experimental example 2. The member of the experimental example 2 has a magnetic body member 251P obtained by quadrisecting the first magnetic part 251, and the Hall element member 300P. FIG. 29 is a perspective view of a member of an experimental example 3. In FIG. 29, the Hall element member 300P is provided, and no magnetic body member is provided. FIG. 30 is a perspective view of a member of an experimental example 4. The member of the experimental example 4 has a magnetic body member 252P obtained by quadrisecting the second magnetic part 252, and the Hall element member 300P.

FIG. 27 (the experimental example 1, the experimental example 5, and the experimental example 6) depicts a member corresponding to the Hall sensor of the embodiment, and FIG. 28 to FIG. 30 (the experimental examples 2 to 4) illustrate members corresponding to the Hall sensor of the comparative example.

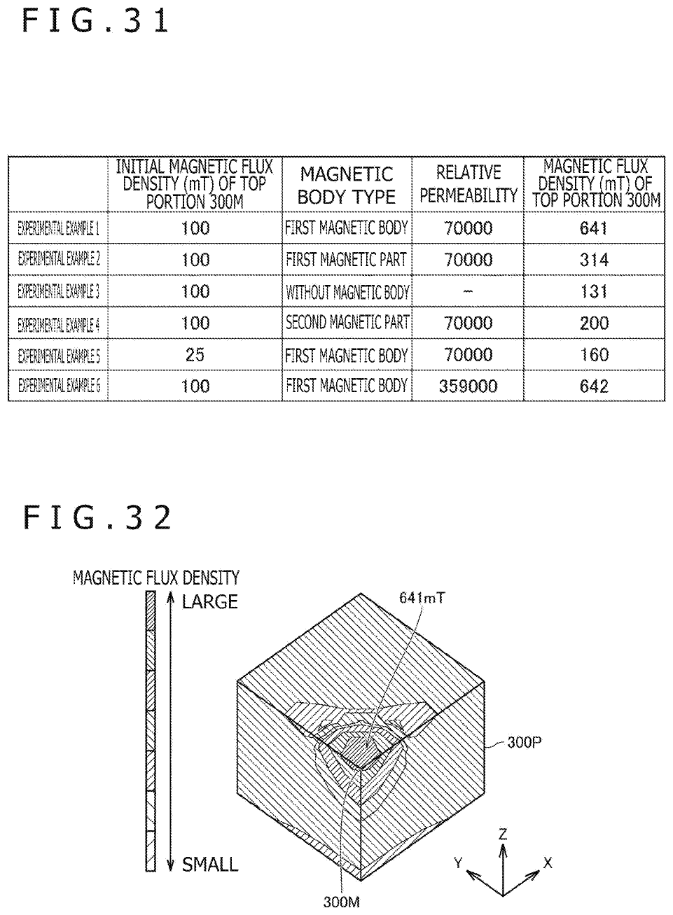

FIG. 31 is a table summarizing the simulation results of the experimental example 1 to the experimental example 6. The initial magnetic flux density of the top portion 300M of each of the experimental examples 1 to 4 and 6 is 100 mT. The initial magnetic flux density is the initial density of the top portion 300M until the magnetic body member is mounted. The initial magnetic flux density of the top portion 300M in the experimental example 5 is 25 mT.

As described in FIG. 27, the type of magnetic body in each of the experimental example 1, the experimental example 5, and the experimental example 6 is the first magnetic body 201. As described in FIG. 28, the type of magnetic body in the experimental example 2 is the first magnetic part 251. As described in FIG. 29, no magnetic body is provided in the experimental example 3. As described in FIG. 30, the type of magnetic body in the experimental example 4 is the second magnetic part 252. The relative permeability of the magnetic body in each of the experimental example 1, the experimental example 2, the experimental example 4, and the experimental example 5 is 70000. The relative permeability of the magnetic body in the experimental example 6 is 359000.

Under the simulation conditions described above, the magnetic flux density of the top portion 300M in the experimental example 1 was 641 mT. The magnetic flux density of the top portion 300M in the experimental example 2 was 314 mT. The magnetic flux density of the top portion 300M in the experimental example 3 was 131 mT. The magnetic flux density of the top portion 300M in the experimental example 4 was 200 mT. The magnetic flux density of the top portion 300M in the experimental example 5 was 160 mT. The magnetic flux density of the top portion 300M in the experimental example 6 was 642 mT. The magnetic flux density of the top portion 300M can be regarded as the same as the magnetic flux density B1.

FIG. 32 to FIG. 37 are diagrams for depicting the magnetic flux densities of the top portion 300M and other parts of the Hall element member 300P in the experimental examples 1 to 6, respectively. In each of FIG. 32 to FIG. 37, as depicted on the left side, the intensity of the magnetic flux density is expressed by the type of hatching and the density of oblique lines configuring the hatching.

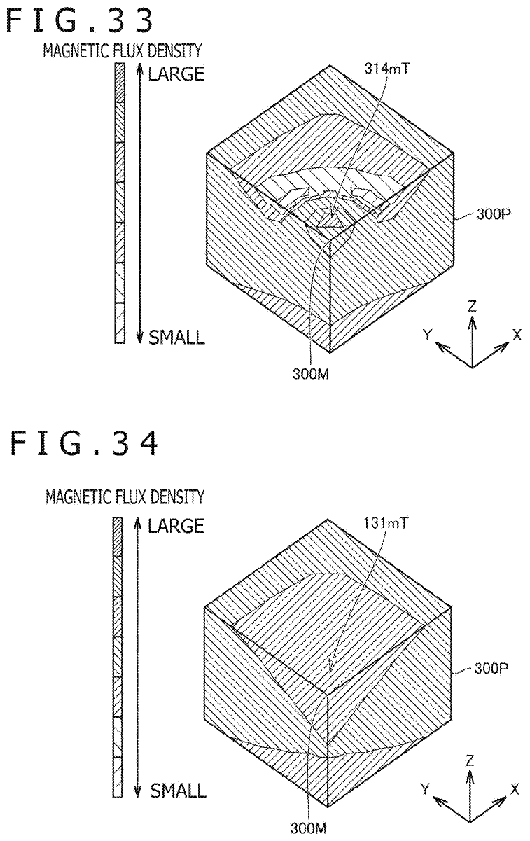

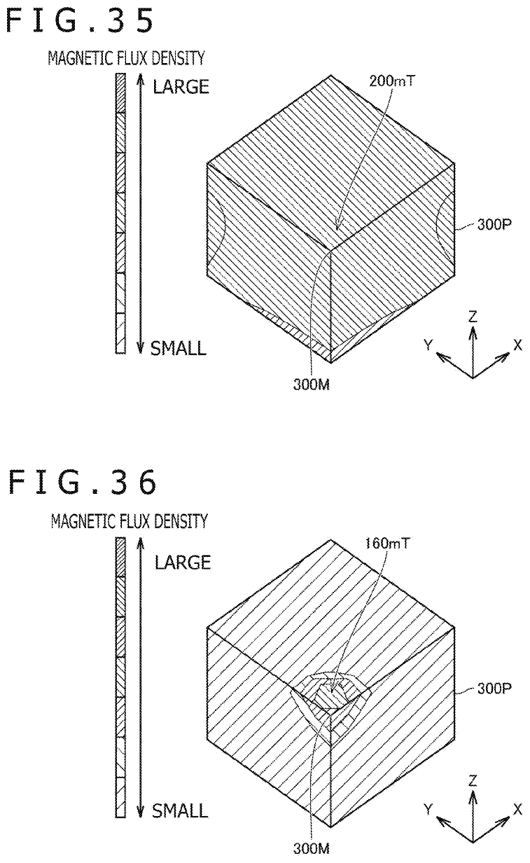

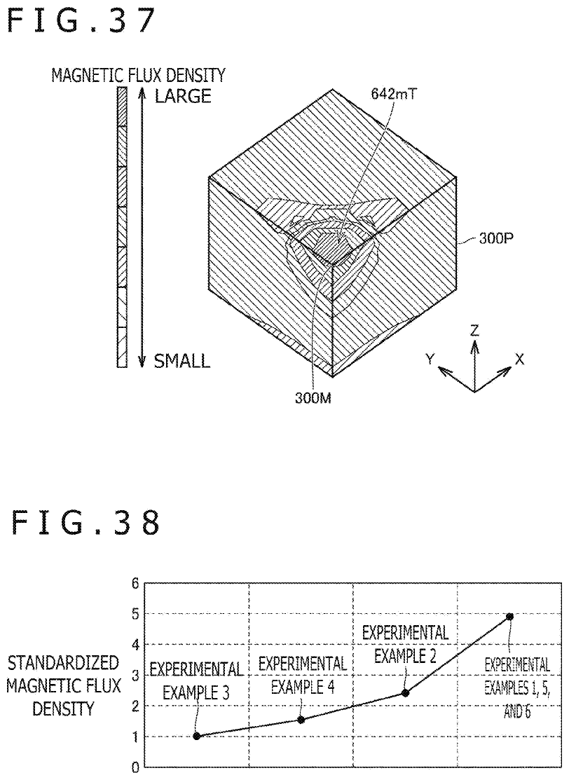

FIG. 32 is a diagram for depicting the magnetic flux density in the experimental example 1. FIG. 33 is a diagram for depicting the magnetic flux density in the experimental example 2. FIG. 34 is a diagram for depicting the magnetic flux density in the experimental example 3. FIG. 35 is a diagram for depicting the magnetic flux density in the experimental example 4. FIG. 36 is a diagram for depicting the magnetic flux density in the experimental example 5. FIG. 37 is a diagram for depicting the magnetic flux density in the experimental example 6.

FIG. 38 is a diagram for depicting the magnetic flux density (magnetic flux density B1) of the top portion 300M in each of the experimental example 1 to the experimental example 6. The vertical axis of FIG. 38 depicts a numerical value (hereinafter, referred to as a “standardized numerical value”) in a case where the magnetic flux density of the top portion 300M in the experimental example 3 (the experimental example having no magnetic body) is standardized to “1.”

As depicted in FIG. 38, the standardized numerical value in the experimental example 3 is 1. The standardized numerical value in the experimental example 4 is approximately 1.5. The standardized numerical value in the experimental example 2 is approximately 2.4. The standardized numerical values in the experimental examples 1, 5, and 6 are each approximately 5.

As depicted in FIG. 38, the experimental examples 1, 5, and 6, which are for the Hall sensor of the embodiment, have a magnetism collection effect approximately 5 times as large as that of the Hall sensor in the experimental example 1. In addition, the experimental examples 1, 5, and 6, which are for the Hall sensor of the embodiment, have a magnetism collection effect approximately 3.2 times as large as that of the Hall sensor in the experimental example 4. In addition, the experimental examples 1, 5, and 6, which are for the Hall sensor of the embodiment, have a magnetism collection effect approximately twice as large as that of the Hall sensor in the experimental example 2. As described above, it has been proved that the Hall sensor of the embodiment has improved the detection sensitivity of the magnetic field.

### Supplementary Note

The above-described embodiments include the following technical ideas.

(1) A Hall sensor according to the present disclosure includes a Hall element having a first principal surface, and a first magnetic body arranged on a side of the first principal surface, in which the first magnetic body has a first surface facing the first principal surface, and an area of a projection surface of the first magnetic body when viewed in plan from an opposite side of the Hall element is larger than an area of the first surface.

According to such a configuration, the magnetic flux density of the first surface facing the Hall element can be increased as compared with the Hall sensor in which the area of the projection surface and the area of the first surface are the same. Thus, since the Hall voltage generated in the Hall element can be increased, the detection sensitivity of the magnetic field can be improved.

(2) In the Hall sensor described in (1), the projection surface is a plane facing the first surface.

According to such a configuration, the manufacturing of the Hall sensor can be simplified.

(3) In the Hall sensor described in (1), a cross section of the first magnetic body perpendicular to the first surface is T-shaped.

According to such a configuration, the manufacturing of the Hall sensor can be simplified.

(4) In the Hall sensor described in any one of (1) to (3), the area of the projection surface is equal to or smaller than an area of the first principal surface.

According to such a configuration, the size of the Hall sensor can be suppressed.

(5) In the Hall sensor described in (4), the area of the projection surface is the same as the area of the first principal surface.

According to such a configuration, the magnetic flux density of the first surface can be increased while suppressing the size of the Hall sensor.

(6) In the Hall sensor described in any one of (1) to (5), the Hall element has a second principal surface facing the first principal surface, and the Hall sensor further includes a second magnetic body arranged on the second principal surface side.

According to such a configuration, since a magnetic flux loop can be formed, the magnetic flux density of the first surface can be increased. Therefore, the detection sensitivity of the magnetic field can further be improved.

(7) In the Hall sensor described in (6), the Hall sensor has a frame in which the Hall element is arranged, and the second magnetic body is arranged between the Hall element and the frame.

According to such a configuration, since a magnetic flux loop can be formed, the magnetic flux density of the first surface can be increased. Therefore, the detection sensitivity of the magnetic field can further be improved.

(8) In the Hall sensor described in (7), the Hall sensor further includes a third magnetic body arranged in the frame on a side opposite to the second magnetic body.

According to such a configuration, even in a case where the second magnetic body is formed by plating and the thickness of the second magnetic body is small, a magnetic flux loop can be formed because the third magnetic body is provided. Therefore, the magnetic flux density of the first surface can be increased.

(9) In the Hall sensor described in (6), the Hall sensor has a frame in which the Hall element is arranged, and the frame is arranged between the Hall element and the second magnetic body.

According to such a configuration, since a magnetic flux loop can be formed, the magnetic flux density of the first surface can be increased. Therefore, the detection sensitivity of the magnetic field can be further improved.

(10) In the Hall sensor described in (6), the Hall sensor has a frame in which the Hall element is arranged, and the frame is the second magnetic body.

According to such a configuration, the number of components can be suppressed as compared with the Hall sensor in which the frame and the second magnetic body are separate.

(11) In the Hall sensor described in any one of (1) to (10), a value obtained by dividing the area of the projection surface by the area of the first surface is 1.1 or more and 16 or less.

According to such a configuration, the magnetic flux density of the first surface facing the Hall element can effectively be increased.

(12) A manufacturing method of a Hall sensor according to the present disclosure includes preparing a Hall element having a principal surface, and forming a magnetic body so as to cover the protruding portion and the recess portion, in which the magnetic body has a magnetic surface facing the principal surface, and an area of a projection surface of the magnetic body when viewed in plan from an opposite side of the Hall element is larger than an area of the magnetic surface.

According to such a configuration, it is possible to manufacture a Hall sensor capable of increasing the magnetic flux density of the first surface facing the Hall element as compared with the Hall sensor in which the area of the projection surface and the area of the first surface are the same. Thus, since the Hall voltage generated in the Hall element can be increased, it is possible to manufacture a Hall sensor in which the detection sensitivity of the magnetic field is improved.

(13) A manufacturing method of a Hall sensor according to the present disclosure includes preparing a Hall element having a principal surface, forming a magnetic body having a magnetic surface, and bonding the Hall element and the magnetic body with an adhesive such that the principal surface and the magnetic surface face each other, and an area of a projection surface of the magnetic body when viewed in plan from an opposite side of the Hall element is larger than an area of the magnetic surface.

According to such a configuration, it is possible to manufacture a Hall sensor capable of increasing the magnetic flux density of the first surface facing the Hall element as compared with the Hall sensor in which the area of the projection surface and the area of the first surface are the same. Thus, since the Hall voltage generated in the Hall element can be increased, it is possible to manufacture a Hall sensor in which the detection sensitivity of the magnetic field is improved.

The embodiments disclosed herein should be considered exemplary in all respects and not restrictive. The scope of the present disclosure is indicated by the claims rather than by the description of the embodiments described above, and is intended to include the meaning equivalent to the claims and all changes within the scope.

What is claimed is:

1. A Hall sensor comprising:
a Hall element having a first principal surface; and
a first magnetic body arranged on a side of the first principal surface,
wherein the first magnetic body has a first surface facing the first principal surface, and
an area of a projection surface of the first magnetic body when viewed in plan from an opposite side of the Hall element is larger than an area of the first surface.

2. The Hall sensor according to claim 1,
wherein the projection surface is a plane facing the first surface.

3. The Hall sensor according to claim 2,
wherein a cross section of the first magnetic body perpendicular to the first surface is T-shaped.

4. The Hall sensor according to claim 1,
wherein the area of the projection surface is equal to or smaller than an area of the first principal surface.

5. The Hall sensor according to claim 4,
wherein the area of the projection surface is the same as the area of the first principal surface.

6. The Hall sensor according to claim 1,
wherein the Hall element has a second principal surface facing the first principal surface, and
the Hall sensor further includes a second magnetic body arranged on the second principal surface side.

7. The Hall sensor according to claim 6,
wherein the Hall sensor has a frame in which the Hall element is arranged, and
the second magnetic body is arranged between the Hall element and the frame.

8. The Hall sensor according to claim 7,
wherein the Hall sensor further includes a third magnetic body arranged in the frame on a side opposite to the second magnetic body.

9. The Hall sensor according to claim 6,
wherein the Hall sensor has a frame in which the Hall element is arranged, and
the frame is arranged between the Hall element and the second magnetic body.

10. The Hall sensor according to claim 6,
wherein the Hall sensor has a frame in which the Hall element is arranged, and
the frame is the second magnetic body.

11. The Hall sensor according to claim 1,
wherein a value obtained by dividing the area of the projection surface by the area of the first surface is 1.1 or more and 16 or less.

12. A manufacturing method of a Hall sensor, the method comprising:
preparing a Hall element having a principal surface;
forming an interlayer film having a protruding portion and a recess portion formed thereon on the principal surface; and
forming a magnetic body so as to cover the protruding portion and the recess portion,
wherein the magnetic body has a magnetic surface facing the principal surface, and
an area of a projection surface of the magnetic body when viewed in plan from an opposite side of the Hall element is larger than an area of the magnetic surface.

13. A manufacturing method of a Hall sensor, the method comprising:
preparing a Hall element having a principal surface;
forming a magnetic body having a magnetic surface; and
bonding the Hall element and the magnetic body with an adhesive such that the principal surface and the magnetic surface face each other,
wherein an area of a projection surface of the magnetic body when viewed in plan from an opposite side of the Hall element is larger than an area of the magnetic surface.
